(19) United States
(12) Patent Application Publication
(10) Pub. No.: US 2026/0332113 A1
(43) Pub. Date: Oct. 22, 2026

(54) AMPLIFIER ACTING AS POWER DISTRIBUTOR AND SWITCH AND OPERATION METHOD FOR THE SAME

(71) Applicant: ELECTRONICS AND TELECOMMUNICATIONS RESEARCH INSTITUTE, Daejeon (KR)

(72) Inventors: Sun Woo KONG, Daejeon (KR); Bong Hyuk PARK, Daejeon (KR); Seung Hun WANG, Daejeon (KR); Hui Dong LEE, Daejeon (KR)

(21) Appl. No.: 19/549,444

(22) Filed: Feb. 25, 2026

(30) Foreign Application Priority Data
Apr. 21, 2025 (KR) 10-2025-0051671

(51) Int. Cl. H03F 3/45; H03F 1/26; H03F 1/56

(52) U.S. Cl. CPC H03F 3/45475; H03F 1/26; H03F 1/56; H03F 2200/294; H03F 2200/318; H03F 2200/451

(57) ABSTRACT

The present disclosure relates to an amplifier operating as a power divider and a switch and an operation method for the same. An active power divider according to an embodiment of the present disclosure may include a power division circuit between one input port and a plurality of output ports; and an amplifier circuit integrating the power division circuit inside.

### TECHNICAL FIELD

The present disclosure relates to an amplifier, and more particularly relates to an amplifier operating as a power divider and a switch and an operation method for the same.

### BACKGROUND ART

For the purpose of beamforming, etc., it may be required to apply channel phase adjustment and/or amplification to a plurality of antennas. For this purpose, according to the existing circuit structure, a low noise amplifier may be directly connected to each antenna and a power divider may be directly connected to this low noise amplifier. Accordingly, a channel capable of adjusting a phase may be connected to a power divider, and the signals of a corresponding channel may be combined through a power combiner in response to each beam.

According to this existing circuit structure, there is a problem that the gain of the front stage close to an antenna is lowered to prevent the suppression of noise on the back stage, finally increasing the noise figure of the entire receiver chain. Accordingly, a new circuit structure is required that may reduce the noise figure of the overall system while maintaining or increasing gains.

### DISCLOSURE

### Technical Problem

The present disclosure is to provide a new amplifier circuit for reducing a noise figure and increasing the gain while having both the functions of a power divider and a switch and an operating method thereof.

The technical objects to be achieved by the present disclosure are not limited to the above-described technical objects, and other technical objects which are not described herein will be clearly understood by those skilled in the pertinent art from the following description.

### Technical Solution

An active power divider according to an embodiment of the present disclosure may include a power division circuit between one input port and a plurality of output ports; and an amplifier circuit integrating the power division circuit inside.

In some embodiments of the present disclosure, a signal input to the one input port may be divided and transmitted to the plurality of output ports. Alternatively, the signal input to the one input port may be switched and transmitted to any one of the plurality of output ports.

In some embodiments of the present disclosure, a first differential amplifier including a first transistor (M1) and a second transistor (M2) may be arranged on an input port (P1) side, a second differential amplifier including a third transistor (M3) and a fourth transistor (M4) may be arranged on a first output port (P2) side, and a third differential amplifier including a fifth transistor (M5) and a sixth transistor (M6) may be arranged on a second output port (P3) side.

In some embodiments of the present disclosure, a first transformer (TF1) may be configured between a gate of the first differential amplifier and the P1.

In some embodiments of the present disclosure, the amplifier circuit may include a second transformer (TF2) that matches between the first differential amplifier and the second differential amplifier and matches between the first differential amplifier and the third differential amplifier.

In some embodiments of the present disclosure, a source of the second differential amplifier and a source of the third differential amplifier may be connected to a common tap of an inductor on the first differential amplifier side of the TF2.

In some embodiments of the present disclosure, current used in the second differential amplifier and the third differential amplifier may flow into a drain of the first differential amplifier.

In some embodiments of the present disclosure, magnetic flux between an inductor on the first differential amplifier side of the TF2 and an inductor on the second differential amplifier side of the TF2 may be shared, and magnetic flux between the inductor on the first differential amplifier side of the TF2 and an inductor on the third differential amplifier side of the TF2 may be shared.

In some embodiments of the present disclosure, magnetic flux between an inductor on the second differential amplifier side and an inductor on the third differential amplifier side of the TF2 may be shared minimally.

In some embodiments of the present disclosure, a third transformer (TF3) may be configured between a drain of the second differential amplifier and the P2, and a fourth transformer (TF4) may be configured between a drain of the third differential amplifier and the P3.

In some embodiments of the present disclosure, at least one of a first amplifier stage between the P1 and the TF1, a second amplifier stage between the TF3 and the P2 or a third amplifier stage between the TF4 and the P3 may be additionally arranged.

An amplifier circuit according to an additional embodiment of the present disclosure may include a transformer that matches between a first differential amplifier on an input port (P1) side and a second differential amplifier on a first output port (P2) side and matches between the first differential amplifier and a third differential amplifier on a second output port (P3) side.

In some embodiments of the present disclosure, a source of the second differential amplifier and a source of the third differential amplifier may be connected to a common tap of an inductor on the first differential amplifier side.

In some embodiments of the present disclosure, current used in the second differential amplifier and the third differential amplifier may flow into a drain of the first differential amplifier.

In some embodiments of the present disclosure, magnetic flux between an inductor on the first differential amplifier side of the TF2 and an inductor on the second differential amplifier side of the TF2 may be shared, and magnetic flux between the inductor on the first differential amplifier side of the TF2 and an inductor on the third differential amplifier side of the TF2 may be shared.

In some embodiments of the present disclosure, magnetic flux between an inductor on the second differential amplifier side and an inductor on the third differential amplifier side of the TF2 may be shared minimally.

In some embodiments of the present disclosure, a signal input to the P1 may be divided and transmitted to the P2 and the P3, or a signal input to the P1 may be switched and transmitted to the P2 or the P3.

A radio transceiver according to an additional embodiment of the present disclosure may include at least one of a plurality of active power dividers respectively connected to a plurality of transmission antennas or a plurality of active power dividers respectively connected to a plurality of reception antennas. Each of the plurality of active power dividers may include an amplifier circuit that integrates a power division circuit between one input port and a plurality of output ports inside.

In some embodiments of the present disclosure, the radio transceiver may be included in a beamformer chip. At least one of phase adjustment of a channel for the plurality of transmission antennas or phase adjustment of a channel for the plurality of reception antennas may be applied by the radio transceiver.

An operation method of an active power divider according to an additional embodiment of the present disclosure may include dividing and transmitting a signal input to the one input port to the plurality of output ports; switching and transmitting the signal input to the one input port to a first output port among the plurality of output ports; or switching and transmitting the signal input to the one input port to a second output port among the plurality of output ports. Here, the active power divider may include an amplifier circuit that integrates a power division circuit between one input port and a plurality of output ports inside.

The features briefly summarized above with respect to the present disclosure are just an exemplary aspect of a detailed description of the present disclosure described below, and do not limit a scope of the present disclosure.

### Technical Effect

According to the present disclosure, a new amplifier circuit for reducing a noise figure and increasing the gain while having both the functions of a power divider and a switch and an operation method thereof may be provided.

Effects achievable by the present disclosure are not limited to the above-described effects, and other effects which are not described herein may be clearly understood by those skilled in the pertinent art from the following description.

### BRIEF DESCRIPTION OF DRAWINGS

FIG. 1 is a diagram representing an example of a block diagram of a beamformer chip to which the present disclosure may be applied.

FIG. 2 is a diagram representing an example of a circuit structure including an active power divider according to the present disclosure.

FIG. 3 is a diagram representing another example of a circuit structure including an active power divider according to the present disclosure.

FIG. 4 represents an example of a detailed implementation diagram of TF2 according to the present disclosure.

FIG. 5 represents an example of a floor plan of TF2 according to the present disclosure.

FIG. 6 is a diagram representing an example of a block diagram of a beamformer chip to which an active power divider according to the present disclosure is applied.

FIG. 7 is a block diagram conceptually representing the structure of an active power divider according to the present disclosure.

FIG. 8 is a block diagram representing a structure to which sequential amplification and passive power division as shown in FIG. 1 are applied.

FIG. 9 represents an example of an operation in which an active power divider according to the present disclosure performs the function of a power divider.

FIG. 10 represents an example in which the S parameter of a P2 output-a P1 input is compared with the S parameter of a P3 output-a P1 input according to the exemplary operation of FIG. 9.

FIG. 11 represents an example of the noise figure (NF) of a P2 output-a P1 input according to the exemplary operation of FIG. 9.

FIG. 12 represents an example of isolation between P2-P3 according to the exemplary operation of FIG. 9.

FIG. 13 represents an example of an operation in which an active power divider according to the present disclosure performs the function of a switch to select a P2 output-a P1 input.

FIG. 14 represents an example of the S parameter of a P2 output-a P1 input according to the exemplary operation of FIG. 13.

FIG. 15 represents an example of the noise figure (NF) of a P2 output-a P1 input according to the exemplary operation of FIG. 13.

FIG. 16 represents an example of isolation between P2-P3 according to the exemplary operation of FIG. 13.

FIG. 17 represents an example of an operation in which an active power divider according to the present disclosure performs the function of a switch to select a P3 output-a P1 input.

FIG. 18 represents an example of the S parameter of a P3 output-a P1 input according to the exemplary operation of FIG. 17.

FIG. 19 represents an example of the noise figure (NF) of a P3 output-a P1 input according to the exemplary operation of FIG. 17.

FIG. 20 represents an example of isolation between P2-P3 according to the exemplary operation of FIG. 17.

FIG. 21 is a diagram for describing an example of an operation method of an active power divider according to the present disclosure.

### MODE FOR INVENTION

As the present disclosure may make various changes and have multiple embodiments, specific embodiments are illustrated in a drawing and are described in detail in a detailed description. But, it is not to limit the present disclosure to a specific embodiment, and should be understood as including all changes, equivalents and substitutes included in an idea and a technical scope of the present disclosure. A similar reference numeral in a drawing refers to a like or similar function across multiple aspects. A shape and a size, etc. of elements in a drawing may be exaggerated for a clearer description. A detailed description on exemplary embodiments described below refers to an accompanying drawing which shows a specific embodiment as an example. These embodiments are described in detail so that those skilled in the pertinent art can implement an embodiment. It should be understood that a variety of embodiments are different each other, but they do not need to be mutually exclusive. For example, a specific shape, structure and characteristic described herein may be implemented in other embodiment without departing from a scope and a spirit of the present disclosure in connection with an embodiment. In addition, it should be understood that a position or an arrangement of an individual element in each disclosed embodiment may be changed without departing from a scope and a spirit of an embodiment. Accordingly, a detailed description described below is not taken as a limited meaning and a scope of exemplary embodiments, if properly described, are limited only by an accompanying claim along with any scope equivalent to that claimed by those claims.

In the present disclosure, a term such as first, second, etc. may be used to describe a variety of elements, but the elements should not be limited by the terms. The terms are used only to distinguish one element from other element. For example, without getting out of a scope of a right of the present disclosure, a first element may be referred to as a second element and likewise, a second element may be also referred to as a first element. A term of “and/or” includes a combination of a plurality of relevant described items or any item of a plurality of relevant described items.

When an element in the present disclosure is referred to as being “connected” or “linked” to another element, it should be understood that it may be directly connected or linked to that another element, but there may be another element between them. Meanwhile, when an element is referred to as being “directly connected” or “directly linked” to another element, it should be understood that there is no another element between them.

As construction units shown in an embodiment of the present disclosure are independently shown to represent different characteristic functions, it does not mean that each construction unit is composed in a construction unit of separate hardware or one software. In other words, as each construction unit is included by being enumerated as each construction unit for convenience of a description, at least two construction units of each construction unit may be combined to form one construction unit or one construction unit may be divided into a plurality of construction units to perform a function, and an integrated embodiment and a separate embodiment of each construction unit are also included in a scope of a right of the present disclosure unless they are beyond the essence of the present disclosure.

A term used in the present disclosure is just used to describe a specific embodiment, and is not intended to limit the present disclosure. A singular expression, unless the context clearly indicates otherwise, includes a plural expression. In the present disclosure, it should be understood that a term such as “include” or “have”, etc. is just intended to designate the presence of a feature, a number, a step, an operation, an element, a part or a combination thereof described in the present specification, and it does not exclude in advance a possibility of presence or addition of one or more other features, numbers, steps, operations, elements, parts or their combinations. In other words, a description of “including” a specific configuration in the present disclosure does not exclude a configuration other than a corresponding configuration, and it means that an additional configuration may be included in a scope of a technical idea of the present disclosure or an embodiment of the present disclosure.

Some elements of the present disclosure are not a necessary element which performs an essential function in the present disclosure and may be an optional element for just improving performance. The present disclosure may be implemented by including only a construction unit which is necessary to implement essence of the present disclosure except for an element used just for performance improvement, and a structure including only a necessary element except for an optional element used just for performance improvement is also included in a scope of a right of the present disclosure.

Hereinafter, an embodiment of the present disclosure is described in detail by referring to a drawing. In describing an embodiment of the present specification, when it is determined that a detailed description on a relevant disclosed configuration or function may obscure a gist of the present specification, such a detailed description is omitted, and the same reference numeral is used for the same element in a drawing and an overlapping description on the same element is omitted.

Hereinafter, examples of the present disclosure for an amplifier operating as a power divider and/or a switch and an operation method thereof are described.

Terms used in the present disclosure may be applied as follows.

A radio transceiver (or a radio frequency (RF) transmitting and receiving end) may correspond to a block that is directly connected to an antenna in a wireless communication system to process an RF signal and convert it into a baseband signal or convert a baseband signal into an RF signal.

A low noise amplifier (LNA) may correspond to the component of a wireless communication system that receives a radio signal, suppresses noise and amplifies and transmits a target signal.

An RF switch is a component that controls the connection of an RF signal, and may correspond to a block capable of controlling the transmission of an RF signal to the first point or the second point.

A power divider is a component used to simultaneously transmit an RF signal to at least two points, and as a representative example, may correspond to a Wilkinson power divider.

A beamformer may correspond to a component that may aim a transmission beam or a reception beam in a specific direction through the cancellation, reinforcement, interference, etc. of radio waves transmitted or received through corresponding antennas by adjusting the phase of a channel connected to a plurality of antennas spaced apart by a predetermined distance (e.g., ½ of a wavelength (typically, lambda)).

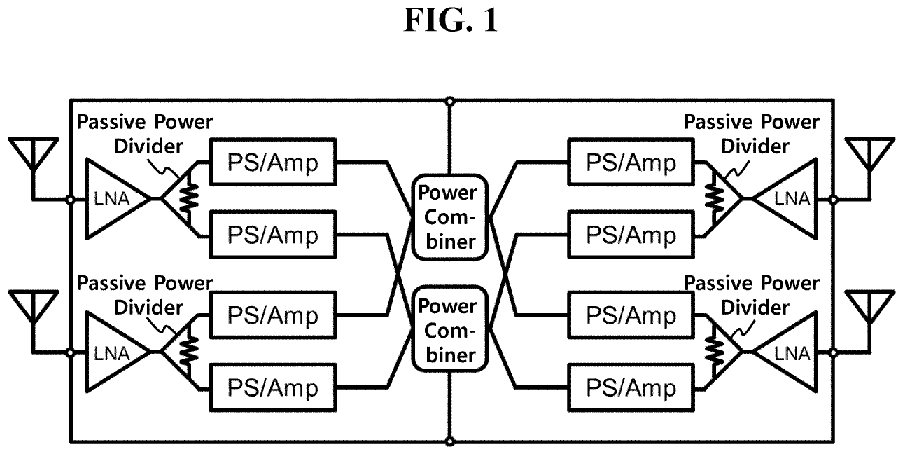

FIG. 1 is a diagram representing an example of a block diagram of a beamformer chip to which the present disclosure may be applied.

In a wireless communication system such as a low orbit satellite communication, at least two beamforming or beam adjustment may be required to respond to a satellite signal at multiple locations. In this case, a low noise amplifier (LNA) directly connected to an antenna as shown in FIG. 1 and a passive power divider directly connected to this low noise amplifier may be applied. A channel capable of adjusting a phase is connected to this passive power divider (e.g., a phase shifter (PS) and an amplifier (Amp), and this channel may be connected to a power combiner again by responding to each beam, combining received signals.

In a ultra-long-distance wireless communication system such as a low orbit satellite communication, ultra-low noise performance is important for securing a link budget. In the existing circuit configuration method, a passive power divider is arranged after a low noise amplifier, so the gain of the front stage closed to an antenna may be reduced in a continuously connected receiver block, making it impossible to suppress noise on the back stage. Accordingly, the noise figure of the entire receiver chain may increase.

To solve this problem, the present disclosure describes a new circuit structure that integrates a passive power divider into the inside of a low noise amplifier. In addition, various examples of a circuit structure including a low noise active power divider that divides power simultaneously with performing low noise amplification are described. In particular, according to the circuit structure of the present disclosure, the function of a path selection switch as well as the function of an active power divider may be additionally provided.

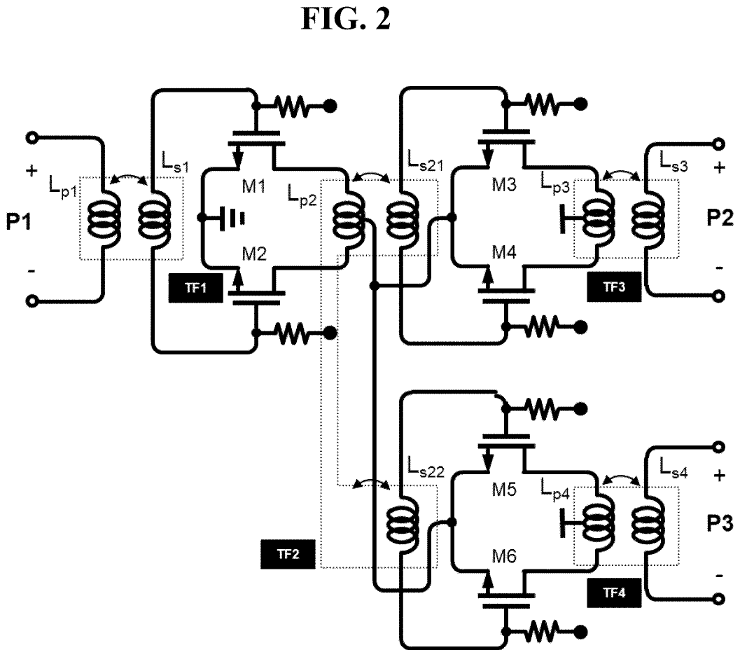

FIG. 2 is a diagram representing an example of a circuit structure including an active power divider according to the present disclosure.

In the present disclosure, it is described by assuming one input port (P1) and two output ports (P2 and P3) as a representative example, but the scope of the present disclosure is not limited thereto, and the examples of the present disclosure may also be applied to a circuit structure that supports active power division/switching for one input port and at least two output ports. For example, the examples of the present disclosure for a 1:2 active power divider may also be applied equally to a 1:3 active power divider and a 1:4 active power divider. Considering chip layout arrangement and signal transmission efficiency, a circuit structure including a 1:2, 1:3 or 1:4 active power divider may be usefully applied.

A signal input to an input port (P1) may be divided and transmitted to the first output port (P2) and the second output port (P3). Alternatively, a signal input to P1 may be transmitted to P2 and then switched and transmitted to P3, or may be transmitted to P3 and then switched and transmitted to P2.

In the example of FIG. 2, M1 to M6 may correspond to the first transistor to the sixth transistor. For example, a transistor may be implemented as MOSFET, but is not limited thereto.

In the example of FIGS. 2, M1 and M2 may configure the first differential amplifier, M3 and M4 may configure the second differential amplifier and M5 and M6 may configure the third differential amplifier.

In the example of FIG. 2, the first transformer (TF1) may perform the role of signal transmission and impedance matching by magnetic coupling between the gate of M1-M2 (i.e., the first differential amplifier) and an input port (P1). The third transformer (TF3) may perform the role of signal transmission and impedance matching by magnetic coupling between the gate of M3-M4 (i.e., the second differential amplifier) and the first output port (P2). The fourth transformer (TF4) may perform the role of signal transmission and impedance matching by magnetic coupling between the gate of M5-M6 (i.e., the third differential amplifier) and the second output port (P3).

In the example of FIG. 2, the second transformer (TF2) may perform the role of dividing a signal, matching between the first differential amplifier composed of M1-M2 and the second differential amplifier composed of M3-M4 and matching between the first differential amplifier composed of M1-M2 and the third differential amplifier composed of M5-M6.

For example, in TF2, between an inductor (Lp2) on the first differential amplifier side composed of M1-M2 and an inductor (Ls21) on the second differential amplifier side composed of M3-M4, signal transmission may be performed validly by sharing magnetic flux.

For example, in TF2, between an inductor (Lp2) on the first differential amplifier side composed of M1-M2 and an inductor (Ls22) on the third differential amplifier side composed of M5-M6, signal transmission may be performed validly by sharing magnetic flux.

For example, in TF2, between an inductor (Ls21) on the second differential amplifier side composed of M3-M4 and an inductor (Ls22) on the third differential amplifier side composed of M5-M6, signal transmission may not be performed validly without sharing or with minimally sharing magnetic flux.

The first differential amplifier composed of M1 and M2 may reuse the current used in the second differential amplifier composed of M3 and M4 and the third differential amplifier composed of M5 and M6. For this purpose, the source of M3-M4 (i.e., the second differential amplifier) and the source of M5-M6 (i.e., the third differential amplifier) may be connected to the common tap of an inductor (Lp2) on the first differential amplifier side composed of M1-M2 in TF2. Accordingly, the current used in the second differential amplifier composed of M3-M4 and the current used in the third differential amplifier composed of M5-M6 may flow into the drain of the first differential amplifier composed of M1-M2.

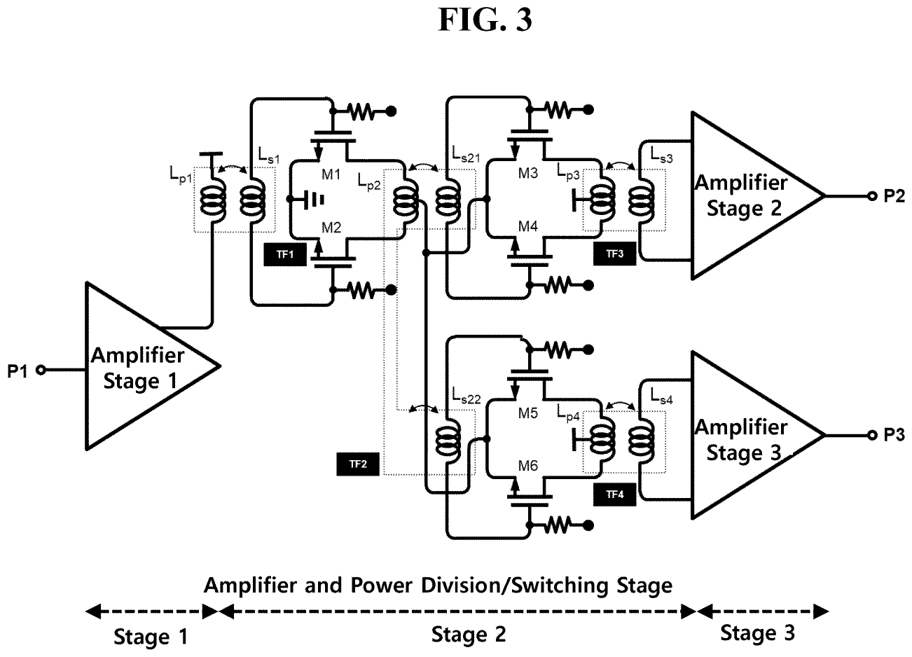

FIG. 3 is a diagram representing another example of a circuit structure including an active power divider according to the present disclosure.

The example of FIG. 3 corresponds to an example in which an amplifier stage is added back and forth in the example of FIG. 2. Since an amplification and power division/switching stage in the example of FIG. 3 is the same as the corresponding structure of an active power divider in the example of FIG. 2, an overlapping description is omitted.

The example of FIG. 3 illustratively represents that amplifier stage 1 is added between P1 and TF1, amplifier stage 2 is added between TF3 and P2 and amplifier stage 3 is added between TF4 and P3. The scope of the present disclosure is not limited thereto, and examples in which at least one of amplifier stage 1, 2 or 3 is added are also included in the scope of the present disclosure.

In the example of FIG. 3, amplifier stage 1 may correspond to the first amplification stage (stage 1). An amplification and power division/switching stage may correspond to the second amplification stage (stage 2). Amplifier stage 2 and/or amplifier stage 3 may correspond to the third amplification stage (stage 3).

The gain may be further increased by adding an amplifier stage on an input port side and/or an output port side in this way, and if necessary, a noise figure may be further improved.

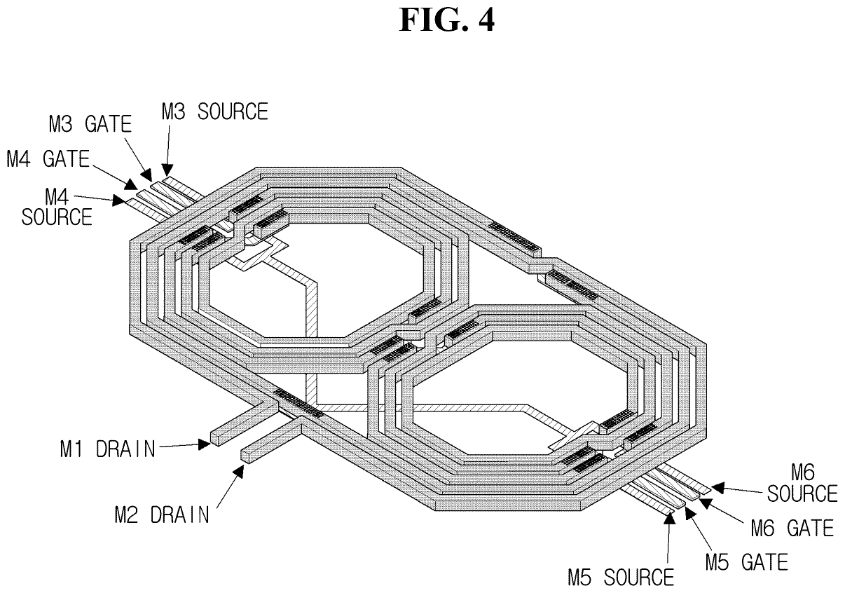

FIG. 4 represents an example of a detailed implementation diagram of TF2 according to the present disclosure.

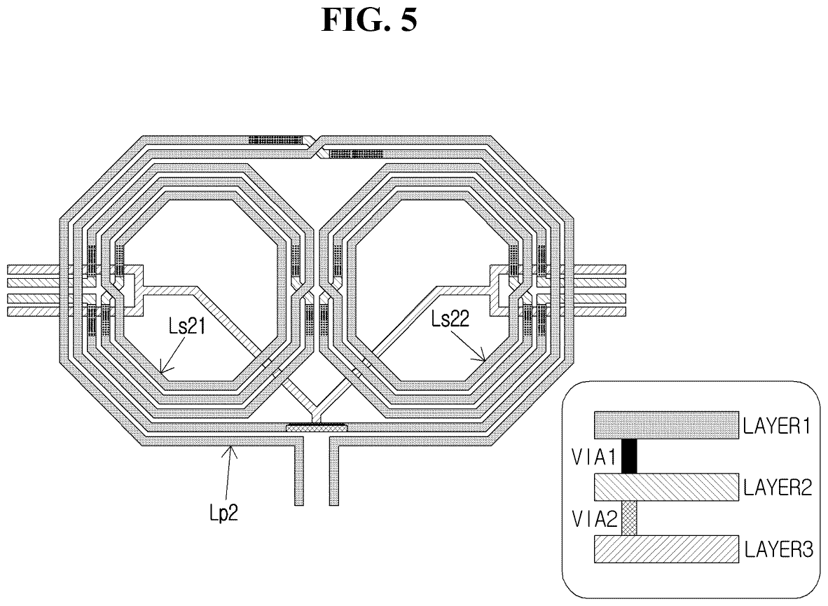

FIG. 5 represents an example of a floor plan of TF2 according to the present disclosure.

As described by referring to FIGS. 2 and 3, TF2 may divide a signal from P1 to P2 and P3 or switch it to P2 or P3. It is because TF2 may perform a role of matching between the first differential amplifier composed of M1-M2 and the second differential amplifier composed of M3-M4 and a role of matching between the first differential amplifier composed of M1-M2 and the third differential amplifier composed of M5-M6.

This TF2 structure may be implemented as shown in the example of FIG. 4. In addition, the structures of Lp2, Ls21 and Ls22 of TF2 may be implemented as shown in the example of FIG. 5. For example, Lp2 may surround Ls21 and Ls22, and Ls21 and Ls22 may be arranged to occupy an area for generating magnetic flux by Lp2 equally on a 50%-50% basis. However, the scope of the present disclosure is not limited to these implementation examples, and other implementation methods are also included within the scope of the present disclosure.

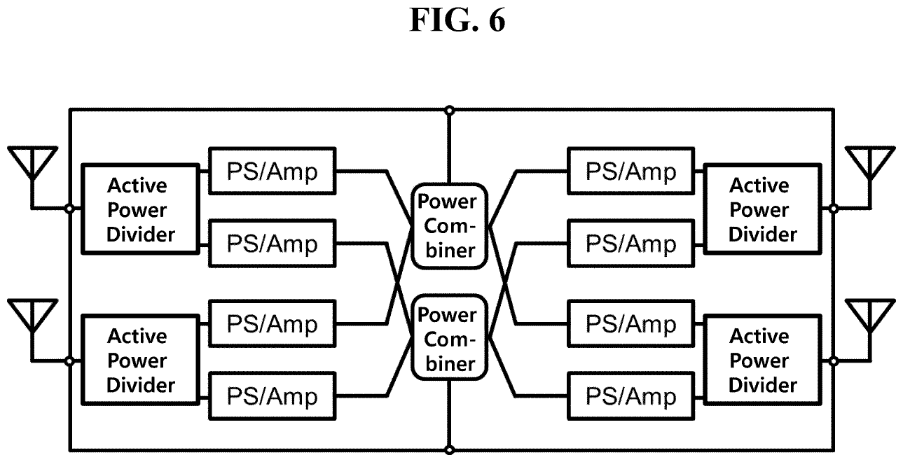

FIG. 6 is a diagram representing an example of a block diagram of a beamformer chip to which an active power divider according to the present disclosure is applied.

Unlike the example of the existing circuit configuration method in FIG. 1 where a passive power divider is arranged after a low noise amplifier, an active power divider that a power division circuit is included inside an amplifier circuit may be applied as in the example of FIG. 6.

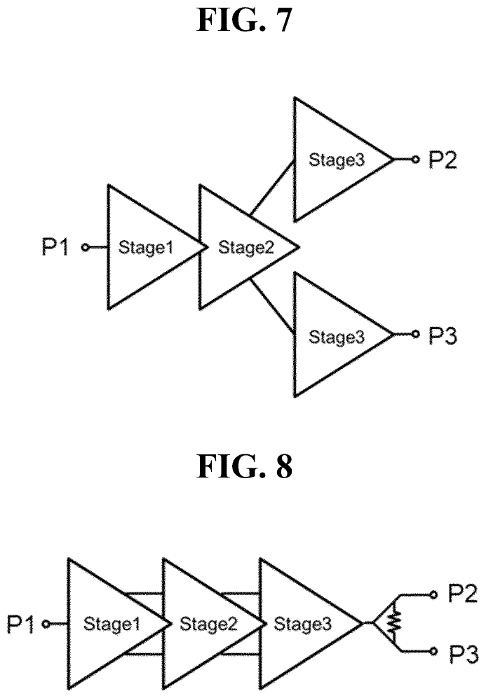

Referring to FIGS. 7 and 8, it is described by comparing the structure of an active power divider according to the present disclosure with the structures of the existing amplifier and a passive power divider.

FIG. 7 is a block diagram conceptually representing the structure of an active power divider according to the present disclosure, and particularly represents a unique structure in which amplification bin power division (or switching) is simultaneously applied in the second amplification stage (stage 2). In contrast, FIG. 8 represents a structure in which sequential amplification and passive power division as in FIG. 1 are applied.

The example of Table 1 corresponds to a calculation result for the system noise figure and gain of a circuit structure including an active power divider according to the present disclosure, as shown in FIG. 7.

TABLE 1

| | Active Power | | Power | |
|---|---|---|---|---|
| FIG. 7 | Divider | Phase Shifter | Combiner | Total |
| Gain (dB) | 19 | −3 | −8 | 8 |
| Noise Figure | 2.1 | 12 | 4.8 | 2.69 |
| (dB) | | | | |

The example of Table 2 corresponds to a calculation result for the system noise figure and gain of a circuit structure where a passive power divider is additionally connected to the output terminal of a three-stage amplifier, as shown in FIG. 8.

TABLE 2

| | Low | Passive | | | |
|---|---|---|---|---|---|
| | Noise | Power | | Power | |
| FIG. 8 | Amplifier | Divider | Phase Shifter | Combiner | Total |
| Gain (dB) | 19 | −4 | −3 | −8 | 4 |
| Noise Figure | 1.8 | 4 | 12 | 4.8 | 3.28 |
| (dB) | | | | | |

In the examples of Table 2 and Table 3, it is assumed that the low noise amplifier of the existing circuit structure in FIG. 8 has a noise figure that is 0.3 dB better than the amplification performance of the active power divider of a circuit structure according to the present disclosure of FIG. 7 and has the same gain. In terms of gain, a three-stage amplifier is connected on a path from P1 to P2 in a circuit structure according to the present disclosure of FIG. 7 and a three-stage amplifier is also connected in the existing circuit structure of FIG. 8, so the same gain is assumed.

In terms of noise figure, considering that a noise caused by an additional path is further included in a circuit structure according to the present disclosure of FIG. 7, it is assumed that the existing circuit structure of FIG. 8 has an excellent noise figure.

In terms of overall system noise figure and gain, it is confirmed that a circuit structure according to the present disclosure of FIG. 7 has a lower noise figure and higher gain than the existing circuit structure of FIG. 8.

Hereinafter, examples of performance results when the active power divider of the present disclosure performs the complex functions of a low noise power divider and a switch are described.

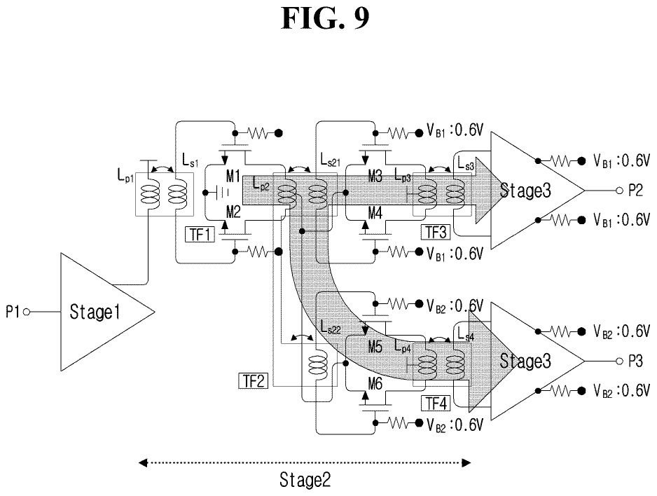

FIG. 9 represents an example of an operation in which an active power divider according to the present disclosure performs the function of a power divider.

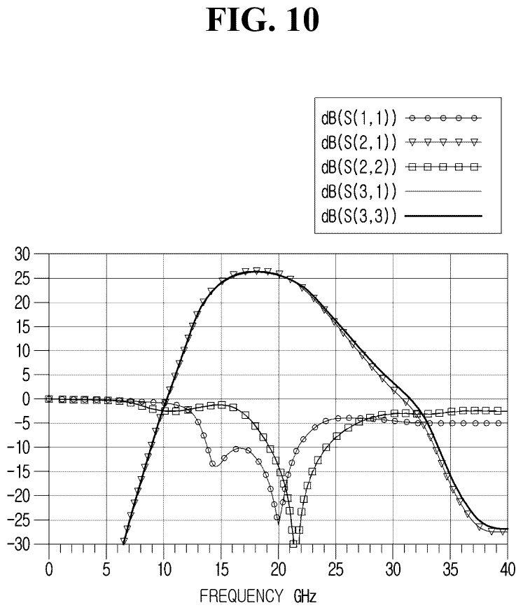

FIG. 10 represents an example in which parameter S of output P2-input P1 is compared with parameter S of output P3-input P1 according to the exemplary operation of FIG. 9.

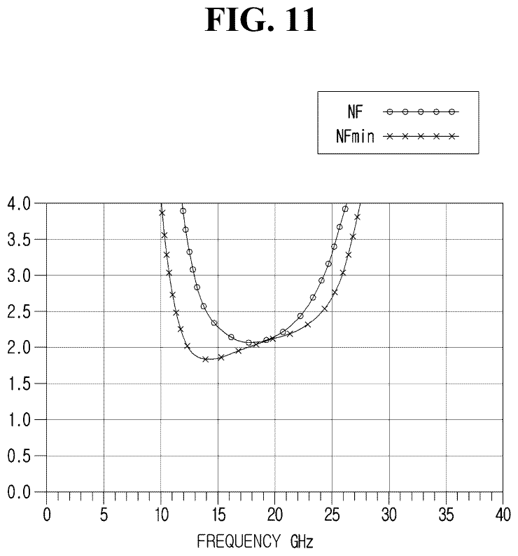

FIG. 11 represents an example of the noise figure (NF) of output P2-input P1 according to the exemplary operation of FIG. 9.

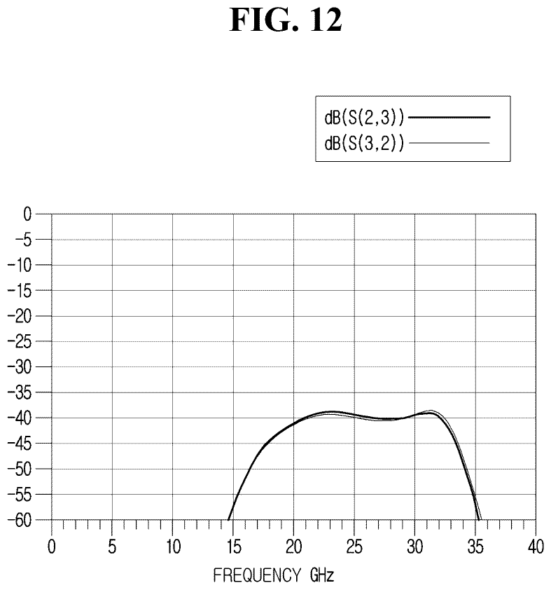

FIG. 12 represents an example of isolation between P2-P3 according to the exemplary operation of FIG. 9.

Referring to FIG. 9, the gate biases of the second differential amplifier of M3-M4, the third differential amplifier of M5-M6 and the third amplification stage (Stage 3) may be turned ON, causing a signal to be transmitted from P1 to both P2 and P3.

In this case, it shows performance of noise figure 2 dB, gain 27 dB and bandwidth 8 GHz. In other words, it means that an active power divider according to the present disclosure may obtain low noise performance, gain performance and bandwidth performance while operating at a level similar to that of a single low noise amplifier. In addition, it may also be confirmed that power division on P1-P2 and P1-P3 paths is performed with high accuracy of 0.1 dB or less.

The isolation between P2 and P3 is less than or equal to −40 dB, which is sufficient to operate as a power divider.

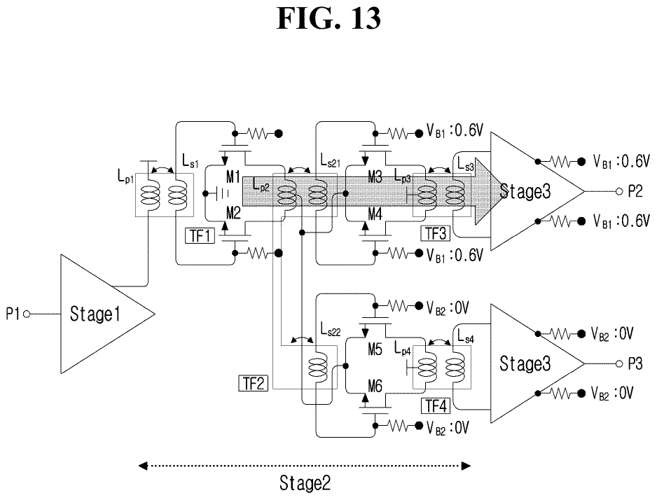

FIG. 13 represents an example of an operation in which an active power divider according to the present disclosure performs the function of a switch to select a P2 output-a P1 input.

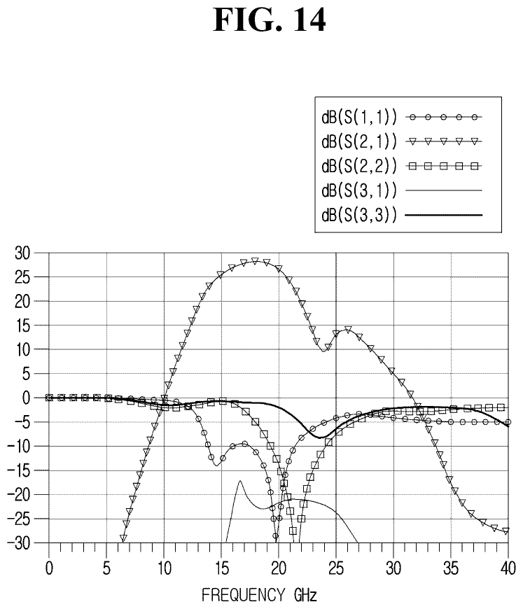

FIG. 14 represents an example of the S parameter of a P2 output-a P1 input according to the exemplary operation of FIG. 13.

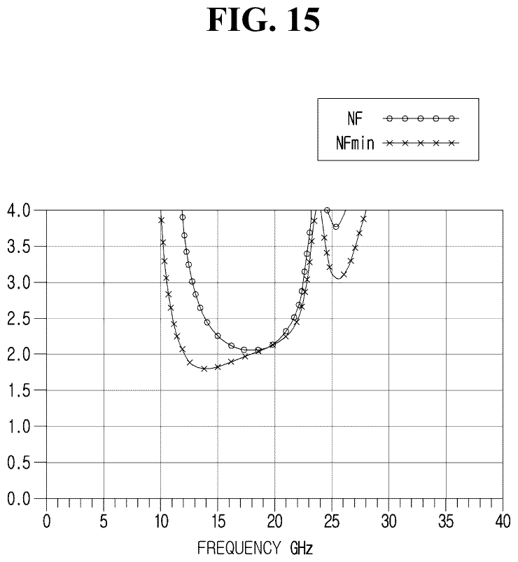

FIG. 15 represents an example of the noise figure (NF) of a P2 output-a P1 input according to the exemplary operation of FIG. 13.

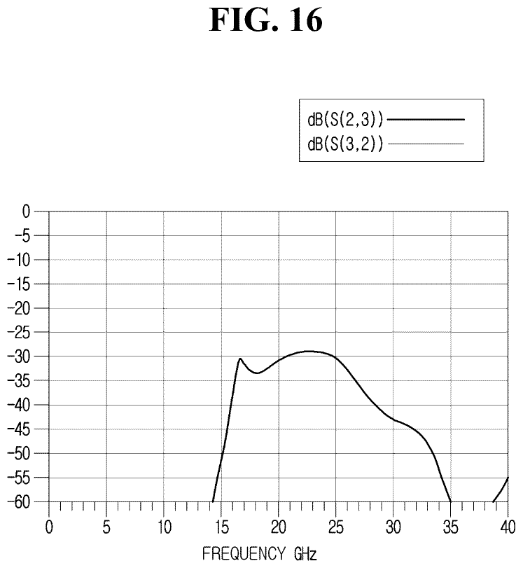

FIG. 16 represents an example of isolation between P2-P3 according to the exemplary operation of FIG. 13.

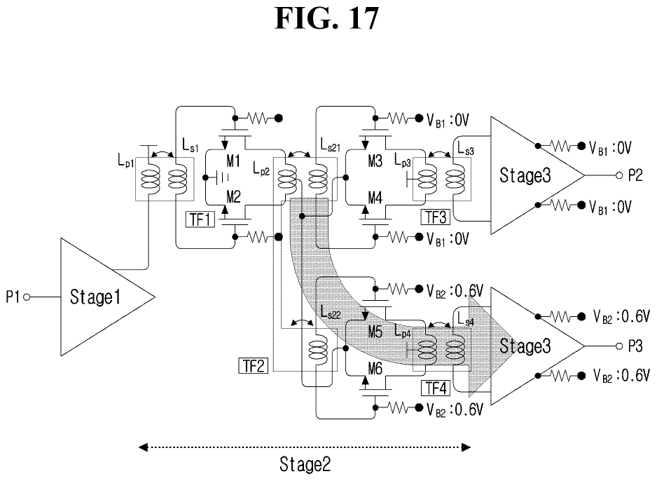

FIG. 17 represents an example of an operation in which an active power divider according to the present disclosure performs the function of a switch to select a P3 output-a P1 input.

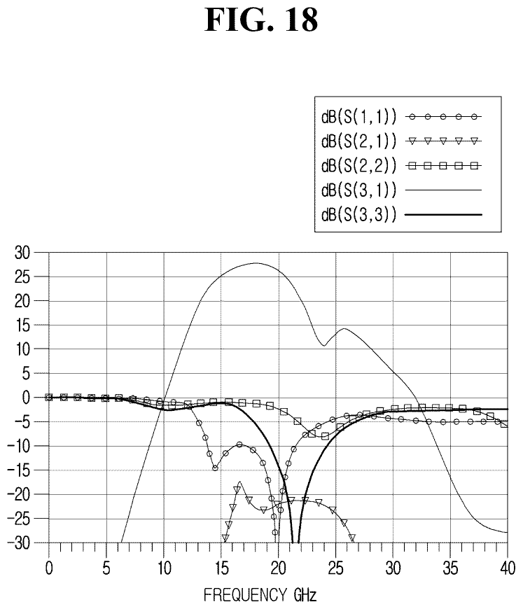

FIG. 18 represents an example of the S parameter of a P3 output-a P1 input according to the exemplary operation of FIG. 17.

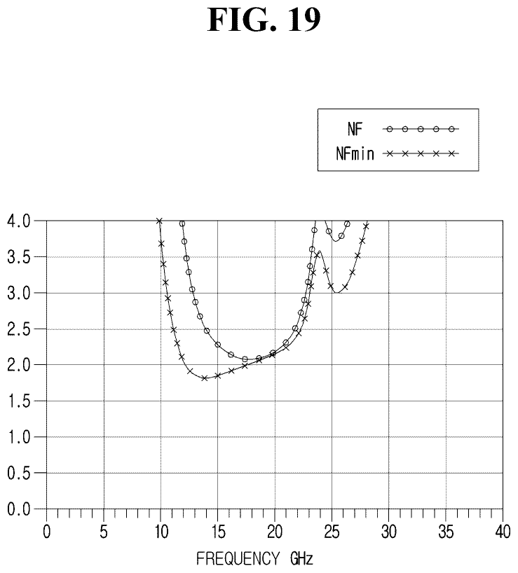

FIG. 19 represents an example of the noise figure (NF) of a P3 output-a P1 input according to the exemplary operation of FIG. 17.

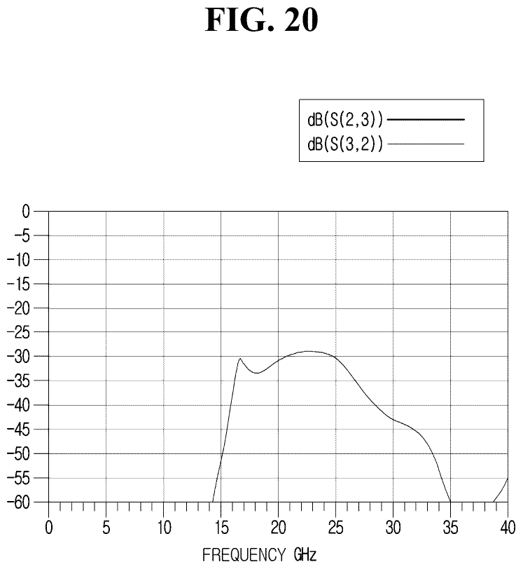

FIG. 20 represents an example of isolation between P2-P3 according to the exemplary operation of FIG. 17.

Referring to the examples of FIGS. 13 to 20, a performance result for a case where an active power divider according to the present disclosure operates as a switch for selecting an RF path may be confirmed.

When a P1-P2 path is selected as in FIG. 13, the gate biases of the second differential amplifier of M3-M4 and the top of the third amplification stage may be turned ON to cause a signal to be transmitted from P1 to P2, and the gate biases of the third differential amplifier of M5-M6 and the bottom of the third amplification stage may be turned OFF to prevent a signal from being transmitted from P1 to P3.

When a P1-P3 path is selected as in FIG. 17, the gate biases of the third differential amplifier of M5-M6 and the bottom of the third amplification stage may be turned ON to cause a signal to be transmitted from P1 to P3, and the gate biases of the second differential amplifier of M3-M4 and the top of the third amplification stage may be turned OFF to prevent a signal from being transmitted from P1 to P2.

In this case, it shows performance of noise figure 2 dB, gain 27 dB and bandwidth 5.9 GHz. In other words, it means that an active power divider according to the present disclosure may obtain both low noise performance and gain performance while operating as an RF switch with performance similar to that of a single low noise amplifier. However, the gain of a null value appears in an out-band, not an in-band, which is an operating band, and a part deteriorated in response to a corresponding null value is observed in a noise figure. In addition, ON-OFF signals show a difference of 50 dB. In addition, it may be confirmed that even when operating as an RF switch, the matching of each port maintains the existing matching performance and the isolation between P2 and P3 is maintained as −30 dB or less.

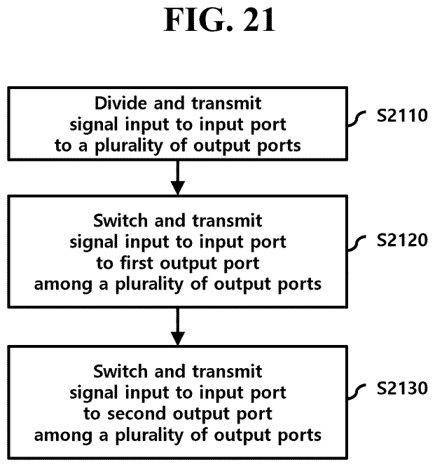

FIG. 21 is a diagram for describing an example of an operation method of an active power divider according to the present disclosure.

Here, an active power divider may include an amplifier circuit that integrates a power division circuit between one input port and a plurality of output ports inside.

In S2110, an active power divider may divide and transmit a signal input to an input port to a plurality of output ports.

In S2120, an active power divider may switch and transmit a signal input to an input port to the first output port among a plurality of output ports.

In S2130, an active power divider may switch and transmit a signal input to an input port to the second output port among a plurality of output ports.

At least one of S2110, S2120 and S2130 may be performed by an active power divider, and even when a plurality of steps are performed, the scope of the present disclosure is not limited by their operating sequence.

A component described in illustrative embodiments of the present disclosure may be implemented by a hardware element. For example, the hardware element may include at least one of a digital signal processor (DSP), a processor, a controller, an application-specific integrated circuit (ASIC), a programmable logic element such as a FPGA, a GPU, other electronic device, or a combination thereof. At least some of functions or processes described in illustrative embodiments of the present disclosure may be implemented by software and software may be recorded in a recording medium. A component, a function and a process described in illustrative embodiments may be implemented by a combination of hardware and software.

A method according to an embodiment of the present disclosure may be implemented by a program which may be performed by a computer and the computer program may be recorded in a variety of recording media such as a magnetic Storage medium, an optical readout medium, a digital storage medium, etc.

A variety of technologies described in the present disclosure may be implemented by a digital electronic circuit, computer hardware, firmware, software or a combination thereof. The technologies may be implemented by a computer program product, i.e., a computer program tangibly implemented on an information medium or a computer program processed by a computer program (e.g., a machine readable storage device (e.g.: a computer readable medium) or a data processing device) or a data processing device or implemented by a signal propagated to operate a data processing device (e.g., a programmable processor, a computer or a plurality of computers).

Computer program(s) may be written in any form of a programming language including a compiled language or an interpreted language and may be distributed in any form including a stand-alone program or module, a component, a subroutine, or other unit suitable for use in a computing environment. A computer program may be performed by one computer or a plurality of computers which are spread in one site or multiple sites and are interconnected by a communication network.

An example of a processor suitable for executing a computer program includes a general-purpose and special-purpose microprocessor and one or more processors of a digital computer. Generally, a processor receives an instruction and data in a read-only memory or a random access memory or both of them. A component of a computer may include at least one processor for executing an instruction and at least one memory device for storing an instruction and data. In addition, a computer may include one or more mass storage devices for storing data, e.g., a magnetic disk, a magnet-optical disk or an optical disk, or may be connected to the mass storage device to receive and/or transmit data. An example of an information medium suitable for implementing a computer program instruction and data includes a semiconductor memory device (e.g., a magnetic medium such as a hard disk, a floppy disk and a magnetic tape), an optical medium such as a compact disk read-only memory (CD-ROM), a digital video disk (DVD), etc., a magnet-optical medium such as a floptical disk, and a ROM (Read Only Memory), a RAM (Random Access Memory), a flash memory, an EPROM (Erasable Programmable ROM), an EEPROM (Electrically Erasable Programmable ROM) and other known computer readable medium. A processor and a memory may be complemented or integrated by a special-purpose logic circuit.

A processor may execute an operating system (OS) and one or more software applications executed in an OS. A processor device may also respond to software execution to access, store, manipulate, process and generate data. For simplicity, a processor device is described in the singular, but those skilled in the art may understand that a processor device may include a plurality of processing elements and/or various types of processing elements. For example, a processor device may include a plurality of processors or a processor and a controller. In addition, it may configure a different processing structure like parallel processors. In addition, a computer readable medium means all media which may be accessed by a computer and may include both a computer storage medium and a transmission medium.

The present disclosure includes detailed description of various detailed implementation examples, but it should be understood that those details do not limit a scope of claims or an invention proposed in the present disclosure and they describe features of a specific illustrative embodiment.

Features which are individually described in illustrative embodiments of the present disclosure may be implemented by a single illustrative embodiment. Conversely, a variety of features described regarding a single illustrative embodiment in the present disclosure may be implemented by a combination or a proper sub-combination of a plurality of illustrative embodiments. Further, in the present disclosure, the features may be operated by a specific combination and may be described as the combination is initially claimed, but in some cases, one or more features may be excluded from a claimed combination or a claimed combination may be changed in a form of a sub-combination or a modified sub-combination.

Likewise, although an operation is described in specific order in a drawing, it should not be understood that it is necessary to execute operations in specific turn or order or it is necessary to perform all operations in order to achieve a desired result. In a specific case, multitasking and parallel processing may be useful. In addition, it should not be understood that a variety of device components should be separated in illustrative embodiments of all embodiments and the above-described program component and device may be packaged into a single software product or multiple software products.

Illustrative embodiments disclosed herein are just illustrative and do not limit a scope of the present disclosure. Those skilled in the art may recognize that illustrative embodiments may be variously modified without departing from a claim and a spirit and a scope of its equivalent.

Accordingly, the present disclosure includes all other replacements, modifications and changes belonging to the following claim.

1. An active power divider, comprising:
a power division circuit between one input port and a plurality of output ports; and
an amplifier circuit integrating the power division circuit inside.

2. The divider of claim 1, wherein:
a signal input to the one input port is divided and transmitted to the plurality of output ports, or
the signal input to the one input port is switched and transmitted to any one of the plurality of output ports.

3. The divider of claim 2, wherein:
a first differential amplifier including a first transistor (M1) and a second transistor (M2) is arranged on an input port (P1) side,
a second differential amplifier including a third transistor (M3) and a fourth transistor (M4) is arranged on a first output port (P2) side, and
a third differential amplifier including a fifth transistor (M5) and a sixth transistor (M6) is arranged on a second output port (P3) side.

4. The divider of claim 3, wherein:
a first transformer (TF1) is configured between a gate of the first differential amplifier and the P1.

5. The divider of claim 3, wherein:
the amplifier circuit includes a second transformer (TF2) that matches between the first differential amplifier and the second differential amplifier, and matches between the first differential amplifier and the third differential amplifier.

6. The divider of claim 5, wherein:
a source of the second differential amplifier and a source of the third differential amplifier are connected to a common tap of an inductor on the first differential amplifier side of the TF2.

7. The divider of claim 6, wherein:
current used in the second differential amplifier and the third differential amplifier flows into a drain of the first differential amplifier.

8. The divider of claim 5, wherein:
magnetic flux between an inductor on the first differential amplifier side of the TF2 and an inductor on the second differential amplifier side of the TF2 is shared, and
magnetic flux between the inductor on the first differential amplifier side of the TF2 and an inductor on the third differential amplifier side of the TF2 is shared.

9. The divider of claim 5, wherein:
magnetic flux between an inductor on the second differential amplifier side and an inductor on the third differential amplifier side of the TF2 is shared minimally.

10. The divider of claim 4, wherein:
a third transformer (TF3) is configured between a drain of the second differential amplifier and the P2, and
a fourth transformer (TF4) is configured between a drain of the third differential amplifier and the P3.

11. The divider of claim 1, wherein at least one of:
a first amplifier stage between the P1 and the TF1,
a second amplifier stage between the TF3 and the P2, or
a third amplifier stage between the TF4 and the P3
is additionally arranged.

12. An amplifier circuit, comprising:
a transformer that matches between a first differential amplifier on an input port (P1) side and a second differential amplifier on a first output port (P2) side, and matches between the first differential amplifier and a third differential amplifier on a second output port (P3) side.

13. The circuit of claim 12, wherein:
a source of the second differential amplifier and a source of the third differential amplifier are connected to a common tap of an inductor on the first differential amplifier side.

14. The circuit of claim 13, wherein:
current used in the second differential amplifier and the third differential amplifier flows into a drain of the first differential amplifier.

15. The circuit of claim 12, wherein:
magnetic flux between an inductor on the first differential amplifier side of the TF2 and an inductor on the second differential amplifier side of the TF2 is shared, and
magnetic flux between the inductor on the first differential amplifier side of the TF2 and an inductor on the third differential amplifier side of the TF2 is shared.

16. The circuit of claim 12, wherein:
magnetic flux between an inductor on the second differential amplifier side and an inductor on the third differential amplifier side of the TF2 is shared minimally.

17. The circuit of claim 12, wherein:
a signal input to the P1 is divided and transmitted to the P2 and the P3, or
the signal input to the P1 is switched and transmitted to the P2 or the P3.

18. The divider of claim 1, wherein:
the active power divider connected to a transmission antenna of a plurality of transmission antennas or a reception antenna of plurality of reception antennas of a radio transceiver.

19. The divider of claim 18, wherein:
the radio transceiver is included in a beamformer chip, and
at least one of phase adjustment of a channel for the plurality of transmission antennas, or phase adjustment of a channel for the plurality of reception antennas is applied by the radio transceiver.

20. An operation method of an active power divider, wherein:
the active power divider includes an amplifier circuit that integrates a power division circuit between one input port and a plurality of output ports inside, and
the operation method includes:
dividing and transmitting a signal input to the one input port to the plurality of output ports; and
switching and transmitting the signal input to the one input port to a first output port among the plurality of output ports; or switching and transmitting the signal input to the one input port to a second output port among the plurality of output ports.
